(19) United States
(12) Patent Application Publication
(10) Pub. No.: US 2012/0285907 A1
(43) Pub. Date: Nov. 15, 2012

(54) Multi-Functional Electronic Device Holder and Method of Use

(76) Inventor: David Edward Emmons, Wells, VT (US)

(21) Appl. No.: 13/465,493

(22) Filed: May 7, 2012

Related U.S. Application Data
(60) Provisional application No. 61/518,617, filed on May 9, 2011.

(51) Int. Cl. H05K 7/00; B23P 17/04

(52) U.S. Cl. 211/26; 29/428

(57) ABSTRACT

This invention is a device that fits into a cup holder converting it into a device that can hold a cup and a variety of electronic devices simultaneously. One embodiment provides access to the electronic devices placed in the device for plugging the electronic devices into electronic connectors or charging cables. Another embodiment has electronic connector and charging cables internally disposed for easier connectivity of electronic devices placed in the device. The device is molded out of flexible material, typically molded by thermoforming, injection molding, blow molding or rotational molding, such as vinyl, polyvinyl chloride, nylon, urethane, polystyrene, polyethylene, aramids, Teflon, leather, thermoplastics or thermosetting polymers with similar properties or other suitable material such that it can securely hold electronic devices in such a way that they can be used hands free, in any cup holder such as on strollers, shopping carts, motorized vehicles, at home or the office.

### BACKGROUND ART

The relatively recent commercialization and proliferation of the cell phone tends to invoke the notion that wireless communication is a recent technology. However, it was a Brazilian Roman Catholic priest and inventor, Father Roberto Landell de Moura, who publicly who first demonstrated a radio broadcast of the human voice on Jun. 3, 1900. De Moura was a student of the physical sciences, and shortly after his radio broadcast over 8 kilometers in Sao Paulo, Brazil he was granted a Brazilian patent on Mar. 9, 1901 for his technology. De Moura secured three U.S. patents for a “Wave Transmitter” (Oct. 11, 1904), a “Wireless Telephone” and “Wireless Telegraph”, both dated Nov. 22, 1904.

Radio telephony was first used in Europe around 1926 on first-class passenger trains that ran between Berlin and Hamburg. It was during this era that radio telephony was first introduced on passenger airplanes for air traffic security. It was Hitler's Germany, however, where radio telephony was first introduced on a large scale in military tanks during World War II. In occupied Germany the police first used surplus tank telephony equipment to run radio patrol cars. In all of these cases the service was confined to specialists that were trained to use the equipment. In the early 1950s ships on the Rhine were among the first to use radio telephony with an untrained end customer as a user.

It proved to be from the 1940s on that gave rise to the technological development which would eventually develop the mobile phone we commonly think of today. Motorola developed the Walkie-Talkie which was a backpacked two-way radio hand-held two-way radio for the US military that was about the size of a man's forearm. The first mobile phone service was established in St. Louis in 1946 which had only three available radio channels and its call set-up required manual operation by a mobile operator. Also in 1946 the Soviet engineers G. Shapiro and I. Zaharchenko successfully tested their version of a mobile phone that was mounted inside a car that could connect to local telephone network and it had a range of up to 20 kilometers.

It was during the 1950s that usable mobile telephony services would emerge and be accepted throughout the developed world, both commercially and culturally. Leonid Kupriyanovich a Soviet radio engineer in 1957 created the LK-1, a portable mobile phone that consisted of a relatively small handset equipped with an antenna and rotary dial. An improved mobile telephone service was introduced in 1964 that had additional channels and more automatic handling of calls to the existing switched telephone network at that time dominated by AT&T and the Bell System in the United States. These additional radio channels in three bands proved to be insufficient to meet the ever increasing demand for vehicle-mounted mobile radio systems.

U.S. Pat. No. 3,339,750 a patent for a wireless phone using an acoustic coupler for incoming calls was issued in 1969, but it did not include the ability for dialing a number for outgoing calls. AT&T submitted a proposal for cellular service to the Federal Communications Commission (FCC) in 1971. It wasn't until 1982 that the FCC approved the AT&T proposal for what would become known as the Advanced Mobile Phone System (AMPS). The FCC allocated frequencies in the 824-894 MHz band for these analog AMPS which eventually were superseded by Digital AMPS in 1990.

A cellular telephone switching plan was first taught in the art by Fluhr and Nussbaum in 1973 and in 1977 a cellular telephone data signaling system was disclosed by Hachenburg et al. U.S. Pat. No. 4,152,647 was issued to Charles A. Gladden and Martin H. Parelman in 1979 for an emergency cellular system for rapid deployment in areas where there was no cellular service.

In an interesting exchange between what would become two of the world's largest cell phone competitors on Apr. 3, 1973, a Motorola researcher, Martin Cooper, made the very first analog mobile phone call using a heavy prototype model and who did he call? Dr. Joel S. Engel of Motorola's competitor at Bell Labs. Motorola and Bell Labs competed fiercely to produce the first portable mobile phone. Cooper was the first inventor named on the U.S. patent application for a Radio Telephone System that ultimately issued as U.S. Pat. No. 3,906,166. It was Motorola that lead the market to develop wireless communication products that would be small enough to use anywhere and participated in the design of the cellular phone.

1G—First Generation mobile phones known as 1G were a technological development that are distinguished from the previous generation mobile phones by their ability to use multiple cell sites and transfer calls from one area to the next as a user moved between cells. The very first commercially automated 1G cellular network was launched in 1979 by NTT in Japan. The network covered an area of Tokyo of over 20 million people with a cellular network that had 23 base stations. Within five years the NTT network covered the entire Japanese population to become the first nation-wide 1G network.

2G—Second Generation, or 2G, mobile phone systems emerged during the 1990s. The 2G primarily used the GSM standard by using digital instead of analog transmission and out-of-band phone-to-network signaling. The 2G network gave rise to huge growth of mobile phone usage and even the advent of prepaid mobile phones.

3G—In the late 90s and into the first part of the 2000s the 2G phones became common place as people began to use mobile phones in their day to day lives. This proliferation ultimately gave rise to an ever increasing demand for data services and access to the internet from these mobile devices. The first pre-commercial trial network with 3G was launched by NTT DoCoMo in Japan in the Tokyo region in May 2001.

4G—By 2009 the industry began developing a data-optimized 4^{th} Generation (4G) technology which promised speed improvements 10-fold over the then existing 3G technology. The first two commercially available 4G networks were the WiMAX standard that was first offered commercially in the U.S. by Sprint and the LTE standard in Scandinavia by TeliaSonera. The 4G network differs from the 3G by eliminating circuit switching by employing an all-IP network.

During this same time period many other hand held or portable electronic devices were developed from mini computers to large capacity storage devices for all types of electronic medium used for business and entertainment. Inevitably this led to many competing makes, models, shapes and sizes of portable electronic devices with different contenders pushing their own technologies, and their vision of market dominance. From the very beginning of the development of these devices most were available with holders for attachment to a person or a vehicle or other location that are functional for their intended use with the particular device for which they were designed. Because of the wide variety of shapes and sizes that exist in these devices, and the fact that a majority of people today own more than one hand held electronic device it would seem that there would exist a single device holder that could accommodate all of these different shapes and sizes. There is no such prior art.

### DISCLOSURE OF THE INVENTION

### Purpose of Invention

The purpose of the invention is to provide a multi-functional device that can hold various personal electronic devices, such as cell phones, smart phones, music and data storage and player devices, and MP3 players. A device that can hold these electronic items in such a way that they can be used hands free, in any cup holder such as on strollers, shopping carts, motorized vehicles, or at home and at the office. Additionally, this invention can be used as a portable viewing stand, and also used as a tripod for smart phones or other electronic devices. Furthermore this holding device has a hidden access area in its base for storing paper money and a spare key. One embodiment of this invention permits the storage or holding of two or more electronic devices at the same time. Also this invention incorporates internal wiring and connectivity in order that the electronic devices being held can be connected electronically for purposes of charging or electronic communication with other devices such as a computer or sound system.

### Description of Problems Solved by Invention

There is currently no single device available that provides a user of various personal electronic devices, such as cell phones, smart phones, music and data storage and player devices, and MP3 players, the flexibility of using these devices hands free while in their vehicle, walking, exercising, at home or at the office. Additionally there is no single device that allows for the multi-functional uses of various personal electronic devices, such as cell phones, smart phones, music and data storage and player devices, and MP3 players, uses such as vertical or horizontal viewing of a smart phone or other electronic device, use as a tripod for a smart phone's, or other electronic device's, camera or video function, of a universal design that fits all devices of various manufacturers.

### How the Invention is an Improvement Over Existing Technology

My invention is a single simple device that does what would take several other devices to accomplish by conforming its shape to that of the device to be held. My invention allows a user of various personal electronic devices, such as cell phones, smart phones, music and data storage and player devices, and MP3 players to use these devices hands free such as while pushing a stroller or driving a vehicle. Further the invention is portable for use in the home or at the office. Additionally, my invention allows for the multi-functional uses of various personal electronic devices, such as cell phones, smart phones, music and data storage and player devices, and MP3 players, uses such as vertical or horizontal viewing of a smart phone, use as a tripod for a smart phone's, or other electronic device's, camera or video function, and my invention is of a universal design that accepts an extensive variety of electronic devices, such as cell phones, smart phones, music and data storage and player devices, and MP3 players, of various manufacturers.

Groups of People and/or Businesses that would Use the Invention

My invention can be used by any and all people desiring a simple way to maximize the hands free aspect of their various personal electronic devices, such as cell phones, smart phones, music and data storage and player devices, and MP3 players, whether while walking with a stroller, exercising or in their vehicle or at home, or in the office.

### Benefits to Users of Invention

The users of my invention will benefit by being able to maximize the hands free aspect of their various personal electronic devices, such as cell phones, smart phones, music and data storage and player devices, and MP3 players, whether while walking with a stroller, exercising or in their vehicle or at home, or in the office. My invention eliminates the need for one to use several various devices to accomplish what my one invention accomplishes. Additionally my invention has other unique features, namely: a hidden access area in its base for storing paper money and a spare key; being able to hold two or more devices; having prewired connectivity for charging a device and/or connecting the device to an electrical current source, a computer, a video player, an audio player, a video recorder, a camera, an audio recorder, a personal electronic device, an MP3 player, a compact disc player, an MP3 recorder, a compact disc recorder, a telephone, a cellular telephone, a global positioning system or electronic mass storage device; and an access port for ease of connecting to a devices charging and connectivity means.

### Brief Description of Invention

The preferred embodiment of my invention is a single piece device made from a flexible pliable material, typically molded by thermoforming, injection molding, blow molding or rotational molding, such as vinyl, nylon, urethane, aramids, Teflon, leather and many other polymers with similar properties, that can hold various personal electronic devices, such as cell phones, smart phones, music and data storage and player devices, and MP3 players of different sizes and shapes. This device can hold these electronic items in such a way that they can be used hands free, in any cup like receptacle, in a stroller, shopping cart, in any vehicle, or at home and at the office. Additionally, my invention can be used as a portable viewing stand, and also a tripod for smart phones. Furthermore this holding device has: a hidden access area in its base for storing paper money and a spare key; being able to hold two or more devices; having prewired connectivity for an electrical current source, a computer, a video player, an audio player, a video recorder, a camera, an audio recorder, a personal electronic device, an MP3 player, a compact disc player, an MP3 recorder, a compact disc recorder, a telephone, a cellular telephone, a global positioning system or electronic mass storage device; and an access port for ease of connecting to a devices charging and connectivity means.

### BRIEF DESCRIPTION OF THE DRAWINGS

FIG. 1 is a front perspective view of the Multi-Functional Electronic Device Holder.

FIG. 2 is a side perspective view of the Multi-Functional Electronic Device Holder.

FIG. 3 is a top perspective view of the Multi-Functional Electronic Device Holder.

FIG. 4 is a front perspective view of the Dual Embodiment Multi-Functional Electronic Device Holder.

FIG. 5 is a side perspective view of the Multi-Functional Electronic Device Holder depicting electronic and internal features.

FIG. 6 is a front perspective view of the Dual Embodiment Multi-Functional Electronic Device Holder depicting electronic and internal features.

FIG. 7 is a top front angular perspective view of the Cup Holder Embodiment Multi-Functional Electronic Device Holder.

### BEST MODES FOR CARRYING OUT THE INVENTION

### I. Preferred Embodiments

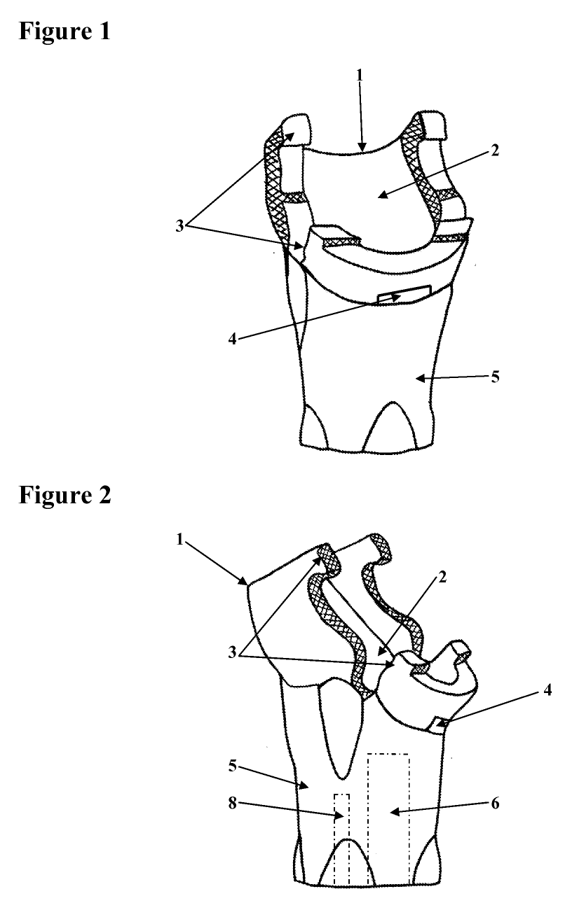

With reference now to the drawings, and in particular to FIGS. 1-7 thereof, a new and novel: Multi-Functional Electronic Device Holder (1); Dual Embodiment Multi-Functional Electronic Device Holder (20); and Cup Holder Embodiment Multi-Functional Electronic Device Holder (31), generally comprised of a single molded piece made from a flexible pliable material, typically molded by thermoforming, injection molding, blow molding or rotational molding, such as vinyl, nylon, urethane, aramids, Teflon, leather and many other polymers with similar properties, which is sufficient in height and width so as to be used in a cup holder or cup receptacle.

### General Description of Reference Numerals in the Description and Drawings

Any actual dimensions listed are those of the preferred embodiment. Actual dimensions or exact hardware details and means may vary in a final product or most preferred embodiment and should be considered means for so as not to narrow the claims of the patent.

### LIST AND DESCRIPTION OF COMPONENT PARTS OF THE INVENTION

(1) Multi-Functional Electronic Device Holder
(2) Electronic Device-Holding Platform
(3) Horizontal Positioning Slot
(4) Device Wire (i.e. Charger) Access Area
(5) Cup Holder Conforming Base
(6) Hidden Access Area For Paper Money
(7) Tripod Function Access Slot
(8) Hidden Key Access Area
(9) Electronic Device Connector
(10) Cable
(11) Cable Connector
(20) Dual Embodiment Multi-Functional Electronic Device Holder
(21) Dual Embodiment Cable Connector
(22) Dual Embodiment Electronic Device-Holding Platform
(23) Dual Embodiment Horizontal Positioning Slot
(24) Dual Embodiment Device Wire (i.e. Charger) Access Area
(25) Dual Embodiment Cup Holder Conforming Base
(26) Dual Embodiment Hidden Access Area For Paper Money
(27) Dual Embodiment Tripod Function Access Slot
(28) Dual Embodiment Hidden Key Access Area
(29) Dual Embodiment Electronic Device Connector
(30) Dual Embodiment Cable
(31) Cup Holder Embodiment Multi-Functional Electronic Device Holder
(32) Cup Holder Embodiment Electronic Device-Holding Platform
(33) Cup Holder Embodiment Horizontal Positioning Slot
(34) Cup Holder Embodiment Cup Receptacle
(35) Cup Holder Embodiment Holder
(36) Cup Holder Embodiment Cup Holder Conforming Base
(37) Cup Holder Embodiment Tripod Function Access Slot
(38) Cup Holder Embodiment Cable
(39) Cup Holder Embodiment Electronic Device Connector
(40) Cup Holder Embodiment Cable Connector

### DETAILED DESCRIPTION OF THE PREFERRED EMBODIMENTS

### A. Multi-Functional Electronic Device Holder Embodiment

The most preferred embodiment of the Multi-Functional Electronic Device Holder (1) depicted in FIGS. 1, 2, 3 and 5 is manufactured and comprised of the following components in their respective functional relationships:

The electronic devices are held in the Electronic Device-Holding Platform (2). The Electronic Device-Holding Platform (2) is set on an angle to the Cup Holder Conforming Base (5) so as to give a stable and advantageous viewing angle of said device. The Electronic Device-Holding Platform (2) is sufficient in length, width, and depth as to be able to accept various makes and models of electronic devices. Additionally the Electronic Device-Holding Platform (2) is comprised of a pliable material, typically molded by thermoforming, injection molding, blow molding or rotational molding, such as vinyl, polyvinyl chloride, nylon, urethane, polystyrene, polyethylene, aramids, Teflon, leather, thermoplastics or thermosetting polymers with similar properties or other suitable material that is sufficiently pliable to permit the Electronic Device-Holding Platform (2) to accept and hold in place a wide variety of electronic devices of various sizes and shapes.

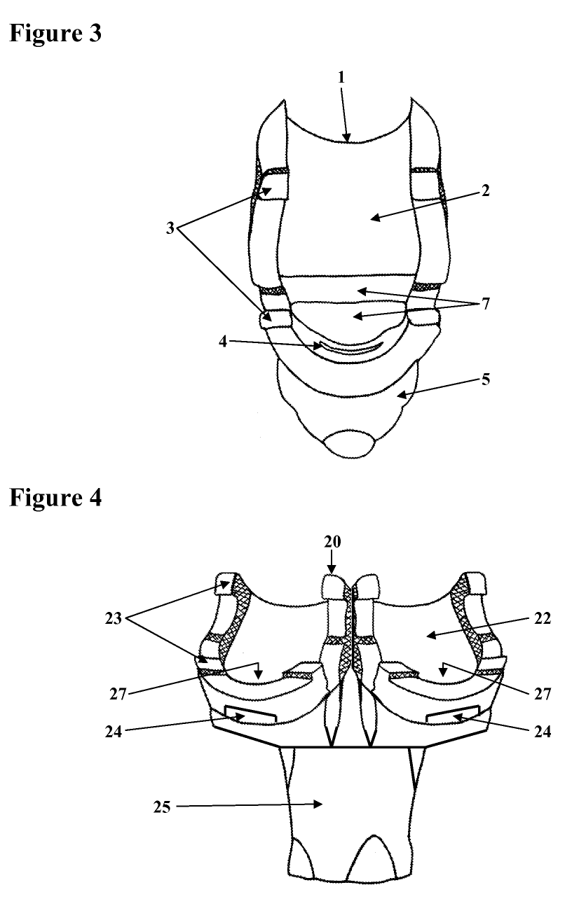

In further detail, still referring to the invention in FIG. 1, FIG. 2, FIG. 3, and FIG. 5 the Electronic Device-Holding Platform (2) has a Horizontal Positioning Slot (3) for the purposes of placing an electronic device in the horizontal viewing position. Further, there is device Wire (i.e. Charger) Access Area (4) for the purposes of easy access to ports in various electronic devices.

In more detail, referring now to the invention in FIG. 3 there is a Tripod Function Access Slot (7) at the base of the Electronic Device-Holding Platform (2) for the purposes of using the Multi-Functional Electronic Device Holder (1) as a stationary tripod. The Tripod Function Access Slot (7) is sufficient in length, width, and depth as to be able to accept various makes and models of smart phones and other electronic devices.

Referring now to FIG. 2 and FIG. 5 there is shown the Multi-Functional Electronic Device Holder (1) having two hidden access areas, a Hidden Access Area For Paper Money (6), and a Hidden Key Access Area (8) in the bottom of its Cup Holder Conforming Base (5). The Hidden Access Area For Paper Money (6) is of sufficient size, such as about 1 inch in diameter and 3 inches deep, as to allow the user to hide a roll of paper money. Further, the Key Access Area (8) is of sufficient size as to allow the user to hide any standard size key. An additional feature of the embodiment depicted in FIG. 5 is the invention's internally wired connectivity comprised of an Electronic Device Connector (9), a Cable (10) and a Cable Connector (11). A user desirous of connecting an electronic device to some other device such as another electronic device, computer or a charging source simply places their device in the Electronic Device-Holding Platform (2) and while doing so the device is appropriately aligned and thereby being placed is plugged into the Electronic Device Connector (9) such that the user's device may now communicate electronically through the Electronic Device Connector (9). The Electronic Device Connector (9) is in turn in electronic communication with the Cable (10) thereby permitting the user's electronic device to electronically communicate through the Cable (10) which in turn is connected to the Cable Connector (11) which in turn is plugged into a user selected device such as another electronic device, computer or a charging source thereby permitting the user's electronic device to electronically communicate with the user selected device such as another electronic device, computer or a charging source.

The construction details of the invention as shown in FIG. 1, FIG. 2, FIG. 3 and FIG. 5 are that the Multi-Functional Electronic Device Holder (1) that may be a material molded by thermoforming, injection molding, blow molding or rotational molding, such as vinyl, polyvinyl chloride, nylon, urethane, polystyrene, polyethylene, aramids, Teflon, leather, thermoplastics or thermosetting polymers with similar properties or any other sufficiently flexible material.

### B. Dual Embodiment Multi-Functional Electronic Device Holder

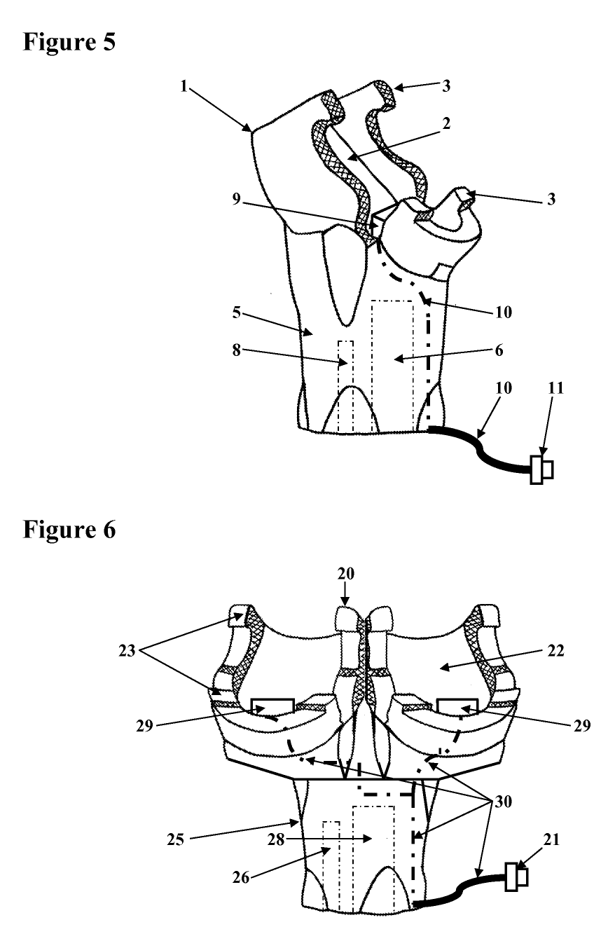

Another embodiment of the device capable of holding two electronic devices is a Dual Embodiment Multi-Functional Electronic Device Holder (20) depicted in FIGS. 4 and 6 which is manufactured and comprised of the following components in their respective functional relationships:

The electronic devices are held in the Dual Embodiment Electronic Device-Holding Platform (22). The Dual Embodiment Electronic Device-Holding Platform (22) is set on an angle to the Dual Embodiment Cup Holder Conforming Base (25) so as to give a stable and advantageous viewing angle of said devices. The Dual Embodiment Electronic Device-Holding Platform (22) is sufficient in length, width, and depth as to be able to accept various makes and models of electronic devices. Additionally the Dual Embodiment Electronic Device-Holding Platform (22) is comprised of a pliable material, typically molded by thermoforming, injection molding, blow molding or rotational molding, such as vinyl, polyvinyl chloride, nylon, urethane, polystyrene, polyethylene, aramids, Teflon, leather, thermoplastics or thermosetting polymers with similar properties or other suitable material that is sufficiently pliable to permit the Dual Embodiment Electronic Device-Holding Platform (22) to accept and hold in place a wide variety of electronic devices of various sizes and shapes.

In further detail, still referring to the invention in FIG. 4 and FIG. 6 the Dual Embodiment Electronic Device-Holding Platform (22) has a Dual Embodiment Horizontal Positioning Slot (23) for the purposes of placing an electronic device in the horizontal viewing position. Further, there is device Dual Embodiment Wire (i.e. Charger) Access Area (24) for the purposes of easy access to ports in various electronic devices.

In more detail, referring now to the invention in FIG. 4 there is a Dual Embodiment Tripod Function Access Slot (27) at the base of the Dual Embodiment Electronic Device-Holding Platform (22) for the purposes of using the Dual Embodiment Multi-Functional Electronic Device Holder (20) as a stationary tripod. The Dual Embodiment Tripod Function Access Slot (27) is sufficient in length, width, and depth as to be able to accept various makes and models of smart phones and other electronic devices.

Referring now to FIG. 6 there is shown the Dual Embodiment Multi-Functional Electronic Device Holder (20) having two hidden access areas, a Dual Embodiment Hidden Access Area For Paper Money (26), and a Dual Embodiment Hidden Key Access Area (28) in the bottom of its Dual Embodiment Cup Holder Conforming Base (25). The Dual Embodiment Hidden Access Area For Paper Money (26) is of sufficient size, such as about 1 inch in diameter and 3 inches deep, as to allow the user to hide a roll of paper money. Further, the Dual Embodiment Key Access Area (28) is of sufficient size as to allow the user to hide any standard size key. An additional feature of the embodiment depicted in FIG. 6 is the invention's internally wired connectivity comprised of a Dual Embodiment Electronic Device Connector (29), a Dual Embodiment Cable (30) and a Dual Embodiment Cable Connector (21). A user desirous of connecting an electronic device to some other device such as another electronic device, computer or a charging source simply places their device in the Dual Embodiment Electronic Device-Holding Platform (22) and while doing so the device is appropriately aligned and thereby being placed is plugged into the Dual Embodiment Electronic Device Connector (29) such that the user's device may now communicate electronically through the Dual Embodiment Electronic Device Connector (29). The Dual Embodiment Electronic Device Connector (29) is in turn in electronic communication with the Dual Embodiment Cable (30) thereby permitting the user's electronic device to electronically communicate through the Dual Embodiment Cable (30) which in turn is connected to the Dual Embodiment Cable Connector (21) which in turn is plugged into a user selected device such as another electronic device, computer or a charging source thereby permitting the user's electronic device to electronically communicate with the user selected device such as another electronic device, computer or a charging source.

### C. Cup Holder Embodiment Multi-Functional Electronic Device Holder

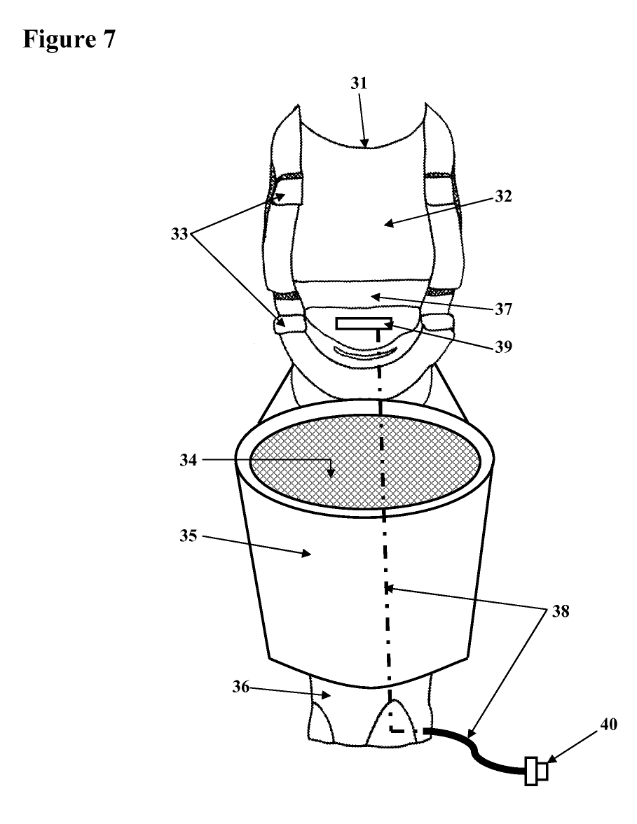

Another embodiment of the device capable of holding a cup in addition to an electronic device is a Cup Holder Embodiment Multi-Functional Electronic Device Holder (31) depicted in FIG. 7 which is manufactured and comprised of the following components in their respective functional relationships:

The electronic devices are held in the Cup Holder Embodiment Electronic Device-Holding Platform (32). The Cup Holder Embodiment Electronic Device-Holding Platform (32) is set on an angle to the Cup Holder Embodiment Holder (35) so as to give a stable and advantageous viewing angle of said devices. The Cup Holder Embodiment Electronic Device-Holding Platform (32) is sufficient in length, width, and depth as to be able to accept various makes and models of electronic devices. Additionally the Cup Holder Embodiment Electronic Device-Holding Platform (32) is comprised of a pliable material, typically molded by thermoforming, injection molding, blow molding or rotational molding, such as vinyl, polyvinyl chloride, nylon, urethane, polystyrene, polyethylene, aramids, Teflon, leather, thermoplastics or thermosetting polymers with similar properties or other suitable material that is sufficiently pliable to permit the Cup Holder Embodiment Electronic Device-Holding Platform (32) to accept and hold in place a wide variety of electronic devices of various sizes and shapes. In order to facilitate the use of this embodiment for simultaneously holding a cup or other user selected article and an electronic device a user may place such cups or user selected articles in the Cup Holder Embodiment Cup Receptacle (34).

In further detail, still referring to the invention in FIG. 7 the Cup Holder Embodiment Electronic Device-Holding Platform (32) has a Cup Holder Embodiment Horizontal Positioning Slot (33) for the purposes of placing an electronic device in the horizontal viewing position. An additional feature of the embodiment depicted in FIG. 7 is the invention's internally wired connectivity comprised of a Cup Holder Embodiment Electronic Device Connector (39), a Cup Holder Embodiment Cable (38) and a Cup Holder Embodiment Cable Connector (40). A user desirous of connecting an electronic device to some other device such as another electronic device, computer or a charging source simply places their device in the Cup Holder Embodiment Electronic Device-Holding Platform (32) and while doing so the device is appropriately aligned and thereby being placed is plugged into the Cup Holder Embodiment Electronic Device Connector (39) such that the user's device may now communicate electronically through the Cup Holder Embodiment Electronic Device Connector (39). The Cup Holder Embodiment Electronic Device Connector (39) is in turn in electronic communication with the Cup Holder Embodiment Cable (38) thereby permitting the user's electronic device to electronically communicate through the Cup Holder Embodiment Cable (38) which in turn is connected to the Cup Holder Embodiment Cable Connector (40) which in turn is plugged into a user selected device such as another electronic device, computer or a charging source thereby permitting the user's electronic device to electronically communicate with the user selected device such as another electronic device, computer or a charging source.

In more detail, referring now to the invention in FIG. 7 there is a Cup Holder Embodiment Tripod Function Access Slot (37) at the base of the Cup Holder Embodiment Electronic Device-Holding Platform (32) for the purposes of using the Cup Holder Embodiment Multi-Functional Electronic Device Holder (31) as a stationary tripod. The Cup Holder Embodiment Tripod Function Access Slot (37) is sufficient in length, width, and depth as to be able to accept various makes and models of smart phones and other electronic devices. The construction details of the invention as shown in FIG. 7 are that the Cup Holder Embodiment Multi-Functional Electronic Device Holder (31) may be made of foam or any other sufficiently flexible material, typically molded by thermoforming, injection molding, blow molding or rotational molding, such as vinyl, polyvinyl chloride, nylon, urethane, polystyrene, polyethylene, aramids, Teflon, leather, thermoplastics or thermosetting polymers with similar properties or other suitable material.

The advantages of the present invention include, without limitation, that it is a multi-functional device that does what it would take several other devices to accomplish. My invention allows a user of various personal electronic devices, such as cell phones, smart phones, and MP3 players to use these devices hands free in the car. Further, the invention is portable for use in the home or at the office. Additionally, my invention allows for the multi-functional uses of various personal electronic devices, such as cell phones, smart phones, and MP3 players, uses such as vertical or horizontal viewing of a smart phone, use as a tripod for a smart phone's camera or video function, and my invention is of a universal design that accepts an extensive variety of electronic devices, such as cell phones, smart phones, and MP3 players, of various manufacturers.

In broad embodiment, the present invention is a Multi-Functional Electronic Device Holder and Method of Use.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. Accordingly, the scope of the invention should be determined not by the embodiments illustrated, but by the claims and their legal equivalents which accompany this application.

Having described my invention, I claim:

1. A multi-functional electronic device holder comprised of:
At least one electronic device holder platform section;
the electronic device holder platform section being a shape and size that will allow a user to place a user selected article in the electronic device holder platform section such that when so placed, the user selected article fits in, and is held securely by, the electronic device holder platform section;
a base section attached to the electronic device holder platform section;
the base section being a shape and size that fits into a holder capable of accepting and supporting a beverage can, bottle, or plastic or glass container.

2. The multi-functional electronic device holder of claim 1 wherein the electronic device holder platform section and the base section are part of a single molded piece molded by at least one process selected from the group consisting of thermoforming, injection molding, blow molding or rotational molding.

3. The multi-functional electronic device holder of claim 2 wherein the electronic device holder platform section and the base section are a single molded piece molded from at least one pliable material selected from the group consisting of vinyl, polyvinyl chloride, nylon, urethane, polystyrene, polyethylene, aramids, Teflon, leather, thermoplastics or thermosetting polymers.

4. The multi-functional electronic device holder of claim 1 wherein the electronic device holder platform section is further comprised of an article receptacle wherein the article receptacle is a shape and size capable of accepting and supporting a beverage can, bottle, or plastic or glass container.

5. The multi-functional electronic device holder of claim 1 wherein the electronic device holder platform section is further comprised of an access area wherein the access area is a size capable of permitting a user to pass there through and have disposed therein at least one user selected item selected from the group consisting of a charging cable, an electronic cable capable of facilitating a computer connection, an electronic cable capable of facilitating electronic communication with an electronic device, an electronic cable capable of facilitating a connection with a sound system, an electronic cable capable of facilitating a connection with a video system, a writing instrument, a key, or money.

6. The multi-functional electronic device holder of claim 1 wherein the multi-functional electronic device holder is further comprised of:
an electronic device connectivity system;
the electronic device connectivity system is comprised of:
an electronic device connection means capable of being placed by a user in electrical and electronic communication with a user selected device;
a cable connected in electrical and electronic communication with the electronic device connection means; and
an electronic connectivity means in electrical and electronic communication with the cable capable of being placed by a user in electrical and electronic communication with at least one user selected item selected from the group consisting of an electrical current source, a computer, a video player, an audio player, a video recorder, a camera, an audio recorder, a personal electronic device, an MP3 player, a compact disc player, an MP3 recorder, a compact disc recorder, a telephone, a cellular telephone, a global positioning system or electronic mass storage device.

7. The multi-functional electronic device holder of claim 1 wherein the base section is further comprised of a storage compartment means capable of storing user selected items.

8. A method of using the multi-functional electronic device holder of claim 1 consisting of the steps of:
selecting a holder of a shape and size that is capable of accepting and supporting a beverage can, bottle, or plastic or glass container;
placing the base section of the multi-functional electronic device holder in the holder;
placing at least one user selected item in the electronic device holder platform section; and
using the user selected item while placed in the electronic device holder platform section.

9. A method of using the multi-functional electronic device holder of claim 4 consisting of the steps of:
selecting a holder of a shape and size that is capable of accepting and supporting a beverage can, bottle, or plastic or glass container;
placing the base section of the multi-functional electronic device holder in the holder;
placing at least one user selected item in the article receptacle;
using the user selected item in the article receptacle;
placing at least one user selected item in the electronic device holder platform section; and
using the user selected item while placed in the electronic device holder platform section.

10. A method of using the multi-functional electronic device holder of claim 5 consisting of the steps of:
selecting a holder of a shape and size that is capable of accepting and supporting a beverage can, bottle, or plastic or glass container;
placing the base section of the multi-functional electronic device holder in the holder;
placing at least one user selected item in the electronic device holder platform section;
placing at least one connection means through the access area;
connecting the connection means to the user selected item;
connecting the connection means to at least one user selected item selected from the group consisting of an electrical current source, a computer, a video player, an audio player, a video recorder, a camera, an audio recorder, a personal electronic device, an MP3 player, a compact disc player, an MP3 recorder, a compact disc recorder, a telephone, a cellular telephone, a global positioning system or electronic mass storage device; and
using the user selected item while placed in the electronic device holder platform section.

11. A method of using the multi-functional electronic device holder of claim 6 consisting of the steps of:
selecting a holder of a shape and size that is capable of accepting and supporting a beverage can, bottle, or plastic or glass container;
placing the base section of the multi-functional electronic device holder in the holder;
placing at least one user selected item in the electronic device holder platform section;
connecting the electronic device connection means to the user selected item;
connecting the electronic connectivity means to at least one user selected item selected from the group consisting of an electrical current source, a computer, a video player, an audio player, a video recorder, a camera, an audio recorder, a personal electronic device, an MP3 player, a compact disc player, an MP3 recorder, a compact disc recorder, a telephone, a cellular telephone, a global positioning system or electronic mass storage device; and
using the user selected item while placed in the electronic device holder platform section.
